(19) United States
(12) Patent Application Publication
(10) Pub. No.: US 2024/0113211 A1
(43) Pub. Date: Apr. 4, 2024

(54) SEMICONDUCTOR DEVICE INCLUDING TWO DIMENSIONAL MATERIAL

(71) Applicants: Samsung Electronics Co., Ltd., Suwon-si (KR); President and Fellows Of Harvard College, Cambridge, MA (US)

(72) Inventors: Yeonchoo CHO, Suwon-si (KR); Elise BRUTSCHEA, Cambridge, MA (US); Philip KIM, Cambridge, MA (US); Hongkun PARK, Lexington, MA (US); Minsu SEOL, Suwon-si (KR)

(73) Assignees: Samsung Electronics Co., Ltd., Suwon-si (KR); President and Fellows Of Harvard College, Cambridge, MA (US)

(21) Appl. No.: 18/475,803

(22) Filed: Sep. 27, 2023

Related U.S. Application Data
(60) Provisional application No. 63/411,248, filed on Sep. 29, 2022.

(30) Foreign Application Priority Data
Nov. 10, 2022 (KR) 10-2022-0149647

(51) Int. Cl. H01L 29/76; H01L 21/02; H01L 29/24; H01L 29/66

(52) U.S. Cl. CPC H01L 29/7606; H01L 21/02568; H01L 29/24; H01L 29/66969

(57) ABSTRACT

A semiconductor device may include a two-dimensional (2D) material having a semiconductor characteristic, a conductive layer on a first surface of the 2D material layer, and an alignment adjusting layer on a second surface of the 2D material layer. The second surface may be different from the first surface. The alignment adjusting layer may adjust an energy-band alignment between the 2D material layer and the conductive layer.

### CROSS-REFERENCE TO RELATED APPLICATION

This application is based on and claims priority under 35 U.S.C. § 119 to U.S. Provisional Patent Application No. 63/411,248, filed on Sep. 29, 2022 in the United States Patent and Trademark Office, and Korean Patent Application No. 10-2022-0149647, filed on Nov. 10, 2022 in the Korean Intellectual Property Office, the disclosures of each of which are incorporated by reference herein in their entirety.

### BACKGROUND

### 1. Field

The present disclosure relates to a semiconductor device including a two-dimensional (2D) material and an apparatus including the semiconductor device.

### 2. Description of the Related Art

Silicon is generally used as a channel layer of a transistor. When forming an electrode on silicon, a contact resistance may be reduced by forming an electrode after over-doping regions of silicon, which are adjacent to a source electrode and a drain electrode. However, because the silicon may not be formed thin while maintaining crystallinity, there is a limitation in scaling.

For scaling of a semiconductor device, research is being conducted to utilize a two-dimensional material that is thin in an atomic layer unit and has a crystallinity as a channel layer instead of silicon.

### SUMMARY

Provided is a structure controlling energy-band alignment at a contact between a two-dimensional material layer of a semiconductor property and a conductive layer.

Provided is a structure capable of reducing a contact resistance between a two-dimensional material layer of a semiconductor property and a conductive layer.

Additional aspects will be set forth in part in the description which follows and, in part, will be apparent from the description, or may be learned by practice of the presented embodiments of the disclosure.

According to an embodiment, a semiconductor device may include a two-dimensional (2D) material layer having a semiconductor characteristic, a conductive layer on a first surface of the 2D material layer, and an alignment adjusting layer on a second surface of the 2D material layer. The alignment adjusting layer may adjust an energy-band alignment between the 2D material layer and the conductive layer. The second surface of the 2D material layer may be different from the first surface of the 2D material layer.

In some embodiments, the second surface of the 2D material layer may be opposite the first surface of the 2D material layer.

In some embodiments, the alignment adjusting layer may overlap the conductive layer in a thickness direction of the 2D material layer.

In some embodiments, a thickness of the alignment adjusting layer may be equal to or less than a thickness of the 2D material layer.

In some embodiments, the alignment adjusting layer may include a 2D material having an insulating property.

In some embodiments, the alignment adjusting layer may include a material capable of providing the 2D material layer with holes.

In some embodiments, a work function of the alignment adjusting layer may be greater than an ionization energy of the 2D material layer.

In some embodiments, the alignment adjusting layer may include at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂.

In some embodiments, the alignment adjusting layer may include a material capable of providing the 2D material layer with electrons.

In some embodiments, a work function of the alignment adjusting layer may be less than an electron affinity of the 2D material layer.

In some embodiments, the alignment adjusting layer may include at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂.

In some embodiments, the 2D material layer may include transition metal dichalcogenide (TMD).

In some embodiments, the TMD may include a metal element and a chalcogen element. The metal element may include one of Mo, W, Nb, V, Ta, Ti, Zr, Hf, Tc, Re, Cu, Ga, In, Sn, Ge, and Pb. The chalcogen element may include one of S, Se, and Te.

In some embodiments, a thickness of the 2D material layer may be 3 nm or less.

In some embodiments, the conductive layer may include a metal material.

In some embodiments, the conductive layer may include a first conductive layer and a second conductive layer. The first conductive layer and the second conductive layer may be spaced apart from each other. The alignment adjusting layer may include a first alignment adjusting layer overlapping the first conductive layer and a second alignment adjusting layer overlapping the second conductive layer in a thickness direction of the 2D material layer.

In some embodiments, the semiconductor device may include a transistor. The 2D material layer may be a channel layer of the transistor. A first one of the first conductive layer and the second conductive layer may be a source electrode of the transistor, and a second one of the first conductive layer and the second conductive layer may be a drain electrode of the transistor.

In some embodiments, the alignment adjusting layer may be spatially spaced apart from the gate electrode of the transistor.

In some embodiments, the first alignment adjustment layer and the second alignment adjusting layer may be connected as different regions of a same alignment adjusting layer.

In some embodiments, the first alignment adjusting layer, the second alignment adjusting layers, or both the first alignment adjusting layer and the second alignment adjusting layer may come into contact with a gate insulating layer of the transistor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram of a thin film structure according to an embodiment;

FIG. 2 is a diagram of a semiconductor device including an alignment adjusting layer according to an embodiment;

FIG. 3 is a diagram showing a result of simulating a density of states (DOS) in a transistor using a two-dimensional material as a channel layer;

FIG. 4 is a diagram showing a result of simulating a DOS of a transistor including an alignment adjusting layer according to an embodiment;

FIGS. 5A to 5C are diagrams illustrating a method of manufacturing a complementary metal oxide semiconductor (CMOS) according to an embodiment;

FIGS. 6A to 6C are diagrams illustrating a method of manufacturing a CMOS according to an embodiment;

FIG. 7 is a diagram of a semiconductor device including one alignment adjusting layer according to an embodiment;

FIG. 8 is a diagram of a semiconductor device having a bottom-gate structure according to an embodiment;

FIG. 9 is a diagram of a semiconductor device having a double-gate structure according to an embodiment;

FIG. 10 is a diagram of a semiconductor device including an alignment adjusting layer according to an embodiment;

FIG. 11 is a diagram of a semiconductor device including an alignment adjusting layer according to an embodiment;

FIG. 12 is a diagram of a semiconductor device including an alignment adjusting layer according to an embodiment;

FIG. 13 is a diagram of a semiconductor device including an alignment adjusting layer according to an embodiment;

FIG. 14 is a diagram of a memory device using a semiconductor device described above as a switching device and including a data storage element connected to the switching device;

FIG. 15 is a diagram of a memory apparatus in which a plurality of memory devices of FIG. 14 are stacked vertically;

FIG. 16 is a block diagram schematically showing an electronic apparatus including a memory apparatus according to an embodiment;

FIG. 17 is a block diagram schematically showing a memory apparatus system including a volatile memory apparatus according to an embodiment; and

FIG. 18 is a schematic diagram of a neuromorphic device including a memory apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, one or more embodiments of the present disclosure will be described in detail with reference to accompanying drawings. In the drawings, like reference numerals denote like components, and sizes of components in the drawings may be exaggerated for convenience of explanation. The embodiments of the disclosure are capable of various modifications and may be embodied in many different forms.

When a layer, a film, a region, or a panel is referred to as being “on” another element, it may be directly on/under/at left/right sides of the other layer or substrate, or intervening layers may also be present. An expression used in the singular encompasses the expression of the plural, unless it has a clearly different meaning in the context. It will be further understood that when a portion is referred to as “comprises” another component, the portion may not exclude another component but may further comprise another component unless the context states otherwise.

The use of the terms of “the above-described” and similar indicative terms may correspond to both the singular forms and the plural forms. Also, the steps of all methods described herein may be performed in any suitable order unless otherwise indicated herein or otherwise clearly contradicted by context.

Also, the terms “ . . . unit”, “ . . . module” used herein specify a unit for processing at least one function or operation, and this may be implemented with hardware or software or a combination of hardware and software.

Furthermore, the connecting lines or connectors shown in the drawings are intended to represent example functional relationships and/or physical or logical couplings between the various elements. It should be noted that many alternative or additional functional relationships, physical connections, or logical connections may be present in a practical device.

The use of any and all examples, or example language provided herein, is intended merely to better illuminate the present disclosure and does not pose a limitation on the scope of the present disclosure unless otherwise claimed.

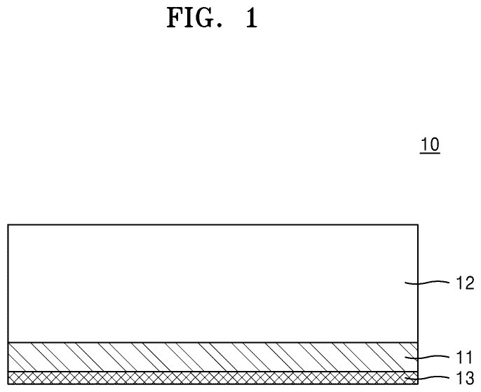

FIG. 1 is a diagram of a thin film structure 10 according to an embodiment. Referring to FIG. 1, the thin film structure 10 may include a two-dimensional (2D) material layer 11 having a semiconductor property, a conductive layer 12 arranged on the 2D material layer 11, and an alignment adjusting layer 13 that adjusts energy-band alignment between the 2D material layer 11 and the conductive layer 12.

The 2D material denotes a material having a 2D crystallization structure. The 2D material may have a monolayer or multilayer structure. Each layer in the 2D material may have a thickness of an atomic level. The 2D material may include, for example, at least one of graphene, black phosphorous, and transition metal dichalcogenide (TMD), but is not limited thereto.

TMD may include, for example, one transition metal from Mo, W, Nb, V, Ta, Ti, Zr, Hf, Tc, and Re, and one chalcogen atom from S, Se, and Te. The TMD may be expressed as, for example, MX2, where M denotes a transition metal and X denotes a chalcogen element. For example, M may include Mo, W, Nb, V, Ta, Ti, Zr, Hf, Tc, Re, etc., and X may include S, Se, Te, etc. Therefore, TMD may include, for example, MOS₂, MoSe₂, MoTe₂, WS₂, WSe₂, WTe₂, ZrS₂, ZrSe₂, HfS₂, HfSe₂, NbSe₂, ReSe₂, etc. Alternatively, TMD may not be expressed as MX2. In this case, for example, TMD may include CuS that is a compound of Cu, that is, transition metal, and S, that is, chalcogen element. In addition, TMD may be a chalcogenide material including a non-transition metal. The non-transition metal may include, for example, Ga, In, Sn, Ge, Pb, etc. In this case, TMD may include a compound of non-transition metal such as Ga, In, Sn, Ge, Pb, etc. and a chalcogen element such as S, Se, and Te. For example, TMD may include SnSe₂, GaS, GaSe, GaTe, GeSe, In₂Se₃, InSnS₂, etc.

As described above, TMD may include one metal element from Mo, W, Nb, V, Ta, Ti, Zr, Hf, Tc, Re, Cu, Ga, In, Sn, Ge, and Pb and one chalcogenide element from S, Se, and Te. However, above-described materials are example, and other materials may be used as TMD materials.

The 2D material layer 11 may have a thickness of about 3 nm or less. For example, the 2D material layer 11 may have a single layer. When applying the 2D material layer 11 to the thin film structure 10, scaling of the thin film structure 10 may be reduced.

The conductive layer 12 may be arranged on the 2D material layer 11. Carriers may be applied to the 2D material via the conductive layer 12. The conductive layer 12 may include metal or a metal compound. For example, the conductive layer 12 may include transition metal such as gold, silver, copper, platinum, palladium, nickel, chrome, cobalt, etc.

In order to form the conductive layer 12 without damage to the 2D material layer 11, an electron affinity of the 2D material layer 11 and a work function of the conductive layer 12 may need to be similar to each other and Fermi level pinning may need to be restrained. In order to extinguish metal induced gap state (MIGS) generating between the conductive layer 12 and the 2D material layer 11, the conductive layer 12 may further include semi-metal having noticeably less density of states (DOS). For example, the conductive layer 12 may further include boron (B), bismuth (Bi), antimony (Sb), etc.

In addition, a type of the 2D material layer 11 having the semiconductor characteristic may be determined according to the energy-band alignment according to the contact between the 2D material layer 11 and the conductive layer 12. The Fermi level of the conductive layer 12, e.g., metal, is closer to a conductive band minimum than a valence band maximum of the 2D material layer 11 having the semiconductor characteristic, and thus, the 2D material layer 11 may be of an n-type when conductive layer 12 comes into contact with the 2D material layer 11. Thus, a transistor including the 2D material layer 11 and the conductive layer 12 may be generally an n-type transistor. The semiconductor device may need a p-type transistor, as well as the n-type transistor, and thus, the type of the 2D material layer 11 may need to be adjusted by controlling the energy-band alignment.

The thin film structure 10 according to an embodiment may further include the alignment adjusting layer 13 on a region in the 2D material layer 11, other than the region coming into contact with the conductive layer 12, the alignment adjusting layer 13 may be used for adjusting the energy-band alignment between the 2D material layer 11 and the conductive layer 12.

The alignment adjusting layer 13 may be arranged on a surface of the 2D material layer 11, other than the surface coming into contact with the conductive layer 12. The alignment adjusting layer 13 may be arranged on a second surface of the 2D material layer 11, which faces or may be opposite a first surface on which the conductive layer 12 is arranged. For example, the conductive layer 12 may be arranged on an upper surface of the 2D material layer 11 and the alignment adjusting layer 13 may be arranged on a lower surface of the 2D material layer 11. The alignment adjusting layer 13 may be arranged to overlap the conductive layer 12 in the thickness direction of the 2D material layer 11. The alignment adjusting layer 13 may provide the 2D material layer 11 with carriers, e.g., electrons or holes. The electrons or holes may reduce the contact resistance between the 2D material layer 11 and the conductive layer 12. Also, the electrons or holes provided from the alignment adjusting layer 13 may adjust the energy-band alignment between the 2D material layer 11 and the conductive layer 12.

The alignment adjusting layer 13 may include an insulating 2D material. Because the alignment adjusting layer 13 includes the 2D material, scaling of the thin film structure 10 may be reduced. For example, the thickness of the alignment adjusting layer 13 may be equal to or less than the 2D material layer 11. Because the alignment adjusting layer 13 includes the 2D material and is stabilized, the material in the alignment adjusting layer 13 may be limited and/or prevented from diffusing into the 2D material layer 11 having the semiconductor characteristic. The alignment adjusting layer 13 is arranged on the region of the 2D material layer 11, which is not in contact with the conductive layer 12, and thus, may less affect the contact between the 2D material layer 11 and the conductive layer 12.

The alignment adjusting layer 13 may include a material that may provide the 2D material layer 11 with holes. For example, the work function of the alignment adjusting layer 13 may be greater than an ionization energy of the 2D material layer 11. The alignment adjusting layer 13 may include at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂. Because the alignment adjusting layer 13 provides the 2D material layer 11 with the holes, the energy-band alignment between the 2D material layer 11 and the conductive layer 12 may be adjusted in the positive direction and the 2D material layer 11 may be of a p-type.

Alternatively, the alignment adjusting layer 13 may include a material that may provide the 2D material layer 11 with electrons. For example, the work function of the alignment adjusting layer 13 may be less than an electron affinity of the 2D material layer 11. The alignment adjusting layer 13 may include at least one of WO₃, electrides, and Mxenes. The alignment adjusting layer 13 may include an electride-based material, for example, at least one of Ca₂N, Sr₂N, Ba₂N, Y₂C, Gd₂C, Tb₂C, Dy₂C, and Ho₂C. The alignment adjusting layer 13 may include an MXene-based material, for example, at least one of Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂. Because the alignment adjusting layer 13 provides the 2D material layer 11 with the electrons, the energy-band alignment between the 2D material layer 11 and the conductive layer 12 may be adjusted in the negative direction and the 2D material layer 11 may be a stabilized n-type.

The thin film structure 10 according to an embodiment may be an element of the semiconductor device. For example, when the semiconductor device includes the transistor, the 2D material layer 11 may be a channel layer and the conductive layer 12 may be a source and/or drain electrode.

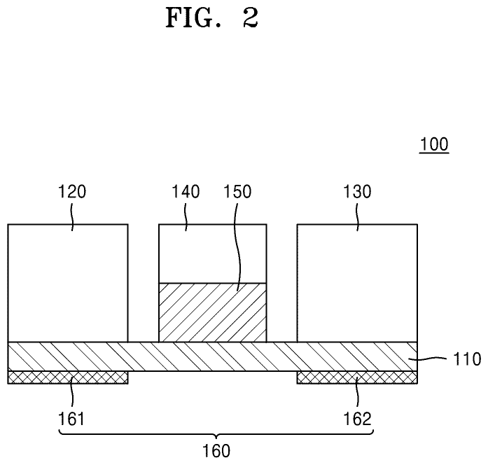

FIG. 2 is a diagram of a semiconductor device 100 including an alignment adjusting layer according to an embodiment. Referring to FIG. 2, the semiconductor device 100 may include a channel layer 110, a source electrode 120 and a drain electrode 130 that are disposed on the channel layer 110 to be spaced apart from each other, a gate electrode 140 spaced apart from the channel layer 110, and a gate insulating layer 150 disposed between the channel layer 110 and the gate electrode 140. The channel layer 110 may correspond to the 2D material layer 11 described above with reference to FIG. 1, and detailed descriptions thereof are omitted.

The source electrode 120 and the drain electrode 130 may be disposed on the channel layer 110 to be spaced apart from each other. The source electrode 120 and the drain electrode 130 may be arranged on the same surface of the channel layer 110. The source electrode 120 and the drain electrode 130 may include an electrically conductive material. For example, at least one of the source electrode 120 and the drain electrode 130 may correspond to the conductive layer 12 described above.

The gate electrode 140 may be disposed on the channel layer 110 and between the source electrode 120 and the drain electrode 130. The gate electrode 140, the source electrode 120, and the drain electrode 130 may be arranged on the same surface of the channel layer 110. According to an embodiment, the gate electrode 140 may include an electrically conductive material. For example, the gate electrode 140 may include metal or a metal compound.

The gate insulating layer 150 may be disposed between the channel layer 110 and the gate electrode 140 so as to electrically disconnect the channel layer 110 and the gate electrode 140 from each other. The gate insulating layer 150 may include an insulating material. The gate insulating layer 150 may include a paraelectric material, a ferroelectric material, etc. For example, the ferroelectric material may include at least one of an oxide ferroelectric material, a polymer ferroelectric material, a fluoride ferroelectric material such as BaMgF₄ (BMF), and/or ferroelectric material semiconductor.

The semiconductor device 100 of FIG. 2 may further include an alignment adjusting layer 160 on a region of the channel layer 110, other than the region coming into contact with the source electrode 120 and the drain electrode 130. The alignment adjusting layer 160 may be spatially spaced from the gate electrode 140. For example, the source electrode 120 and the drain electrode 130 may be disposed on the upper surface of the channel layer 110, and the alignment adjusting layer 160 may be disposed on a lower surface of the channel layer 110. The alignment adjusting layer 160 may include first and second alignment adjusting layers 161 and 162 that are spaced apart from each other on the lower surface of the channel layer 110. The first alignment adjusting layer 161 may overlap the source electrode 120 in the thickness direction of the channel layer 110, and the second alignment adjusting layer 162 may overlap the drain electrode 130 in the thickness direction of the channel layer 110.

The first and second alignment adjusting layers 161 and 162 may include a material that may provide the channel layer 110 with holes. For example, the work function of the first and second alignment adjusting layers 161 and 162 may be greater than an ionization energy of the channel layer 110. The first and second alignment adjusting layers 161 and 162 may each include at least one of RuCl₃, NbS₂, and MoO₃. Because the first and second alignment adjusting layers 161 and 162 provide the channel layer 110 with the holes, the energy-band alignment between the channel layer 110 and the source/drain electrodes 120 and 130 is adjusted in the positive direction. Thus, the semiconductor device 100 of FIG. 2 may be a p-type transistor.

The first and second alignment adjusting layers 161 and 162 may include a material that may provide the channel layer 110 with electrons. For example, the work function of the first and second alignment adjusting layers 161 and 162 may be less than an electron affinity of the channel layer 110. The first and second alignment adjusting layers 161 and 162 may each include at least one of WO₃, electrides, and Mxenes. Because the first and second alignment adjusting layers 161 and 162 provide the channel layer 110 with the electrons, the energy-band alignment between the channel layer 110 and the source/drain electrodes 120 and 130 is adjusted in the negative direction. Thus, the semiconductor device 100 of FIG. 2 may be an n-type transistor.

As described above, when the channel layer 110 includes the 2D material having the semiconductor characteristics and the source/drain electrodes 120 and 130 that are the conductive layers are formed on the channel 110, the channel layer 110 may be of an n-type due to the energy-band alignment between the channel layer 110 and the source/drain electrodes 120 and 130. Thus, even when the first and second alignment adjusting layers 161 and 162 do not exist, the transistor including the channel layer 110 may be an n-type transistor. However, the transistor in which the first and second alignment adjusting layers 161 and 162 providing the channel layer 110 with electrons are arranged may be stably operated.

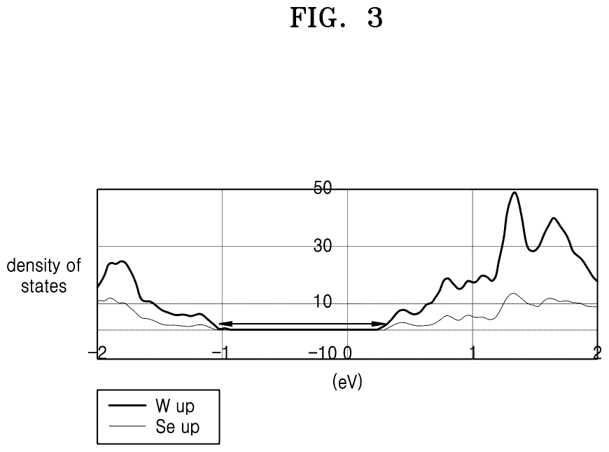

FIG. 3 is a diagram showing a result of simulating a density of states (DOS) in a transistor using a 2D material as the channel layer 110. A transistor with the channel layer 110 was manufactured by using WSe₂. The DOS of the transistor including WSe₂ is shown in FIG. 2. It may be identified that the DOS in the positive direction is closer to 0 than the DOS in the negative direction. Therefore, it may be predicted that the transistor including WSe₂ may be operated as the n-type transistor.

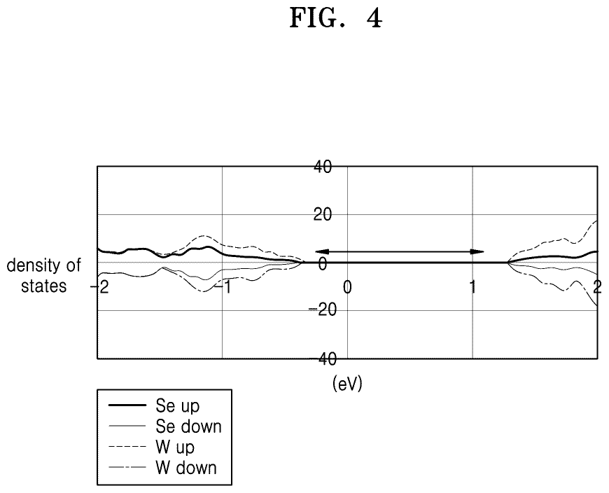

FIG. 4 is a diagram showing a result of simulating a DOS of a transistor including an alignment adjusting layer 160 according to an embodiment. A channel layer was formed by using WSe₂, and a transistor with the alignment adjusting layer was manufactured by using RuCl₃. The DOS of the transistor including the alignment adjusting layer is shown in FIG. 4. It may be identified that the DOS in the negative direction is closer to 0 than the DOS in the positive direction. It may be identified that the alignment adjusting layer may adjust the energy-band alignment between the channel layer and the source and/or drain electrode. It may be predicted that the transistor including RuCl₃ may be operated as a p-type transistor.

When a logic circuit includes both the n-type transistor and the p-type transistor, efficiency of the logic circuit may be improved. According to the semiconductor device of an embodiment, a complementary metal oxide semiconductor (CMOS) including the n-type transistor and the p-type transistor may be manufactured through one process.

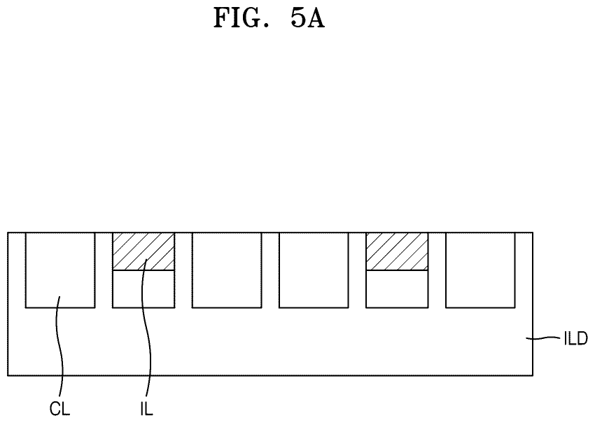

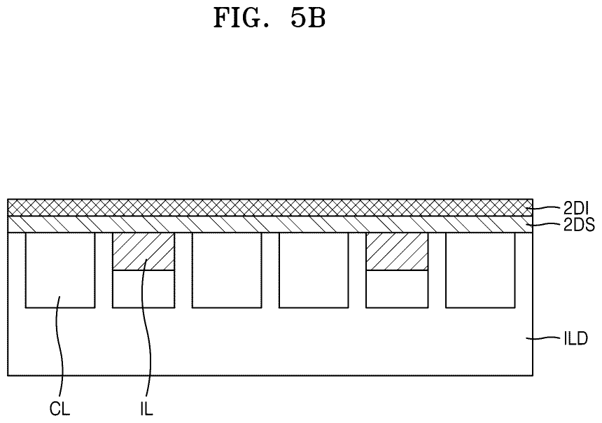

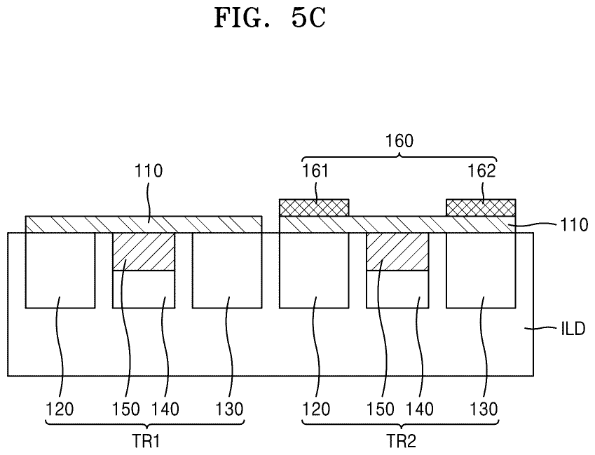

FIGS. 5A to 5C are diagrams illustrating a method of manufacturing a CMOS according to an embodiment.

As shown in FIG. 5A, a plurality of conductive layers CL and a plurality of insulating layers IL may be formed in an interlayer insulating layer ILD. For example, six conductive layers CL and two insulating layers IL that are spaced apart from one another may be formed in the interlayer insulating layer ILD. The conductive layer CL may be formed of metal and/or metal compound, and the insulating layer IL may be formed of a paraelectric material and/or a ferroelectric material.

From among six conductive layers CL, upper surfaces of four conductive layers CL may be exposed along with the upper surface of the interlayer insulating layer ILD, and two conductive layers CL may be formed to be impregnated in the interlayer insulating layer ILD. In addition, the insulating layers IL may be formed respectively on the two impregnated conductive layers CL, and upper surfaces of the insulating layers IL may be exposed along with the upper surface of the interlayer insulating layer ILD.

As shown in FIG. 5B, a 2D material layer 2DS having semiconductor characteristics and a 2D material layer 2DI having insulating property may be sequentially formed on the upper surface of the interlayer insulating layer ILD. A lower surface of the 2D material layer 2DS having the semiconductor characteristic may be in contact with the four conductive layers CL and two insulating layers IL, and an upper surface of the 2D material layer 2DS having the semiconductor characteristic may be in contact with the 2D material layer 2DI having the insulating property. The 2D material layer 2DS of the semiconductor characteristic may correspond to the material in the 2D material layer 11 of FIG. 1, and the 2D material layer 2DI of the insulating property may correspond to the material in the alignment adjusting layer 13 of FIG. 2. For example, a work function of the 2D material layer 2DI having the insulating property may be greater than the ionization energy of the 2D material layer 2DS having the semiconductor characteristic. The 2D material layer 2DI having the insulating property may include at least one of RuCl₃, NbS₂, and MoO₃.

As shown in FIG. 5C, the 2D material layer 2DS having the semiconductor characteristic and the 2D material layer 2DI having the insulating property may be patterned to form the channel layer 110 and the alignment adjusting layer 160, and then, two transistors TR1 and TR2 may be manufactured. The first transistor TR1 may not include the alignment adjusting layer 160, and the second transistor TR2 may include the alignment adjusting layer 160.

One of the two conductive layers CL that are included in the first transistor TR1 and in contact with the channel layer 110 may become the source electrode 120 and the other may become the drain electrode 130. In addition, the conductive layer CL that is in the first transistor TR1 and spaced apart from the channel layer 110 may become the gate electrode 140. The first transistor TR1 does not include the alignment adjusting layer 160, and thus, the first transistor TR1 may be an n-type transistor.

One of the two conductive layers CL that are included in the second transistor TR2 and in contact with the channel layer 110 may become the source electrode 120 and the other may become the drain electrode 130. In addition, the conductive layer CL that is in the second transistor TR2 and spaced apart from the channel layer 110 may become the gate electrode 140. The second transistor TR2 includes the alignment adjusting layer 160, and thus, the second transistor TR2 may be a p-type transistor.

In FIGS. 5A to 5C, the p-type transistor is manufactured by using the alignment adjusting layer 160, but one or more embodiments are not limited thereto. The n-type transistor may be manufactured by using the alignment adjusting layer 160. For example, a 2D material layer (not shown) having a first type insulating property may be formed on the 2D material layer 2DI having the insulating property overlapping three conductive layers CL in the thickness direction of the 2D material layer 2DS having the semiconductor characteristic, and a 2D material layer (not shown) having a second type insulating property may be formed on the 2D material layer 2DS having the semiconductor characteristic overlapping three other conductive layers CL in the thickness direction of the 2D material layer 2DS having the semiconductor characteristic. The 2D material layer of the first type insulating property may include a material that may provide the 2D material layer 2DS having the semiconductor characteristic with electrons, and the 2D material layer of the second type insulating property may include a material that may provide the 2D material layer 2DS having the semiconductor characteristic with holes. The 2D material layer 2DS of the semiconductor characteristic, the 2D material layer of the first type insulating property, and the 2D material layer of the second type insulating property are patterned, and then, the n-type transistor and the p-type transistor may be manufactured.

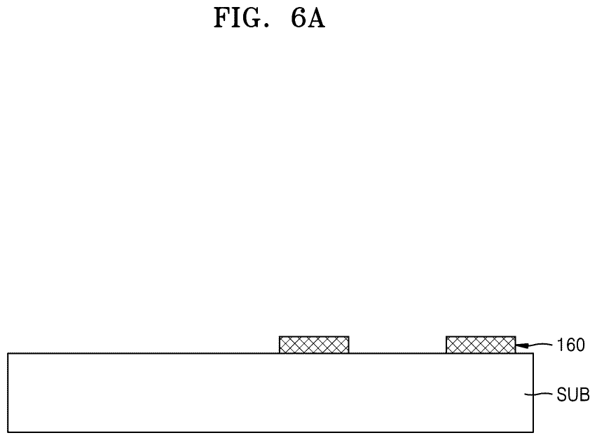

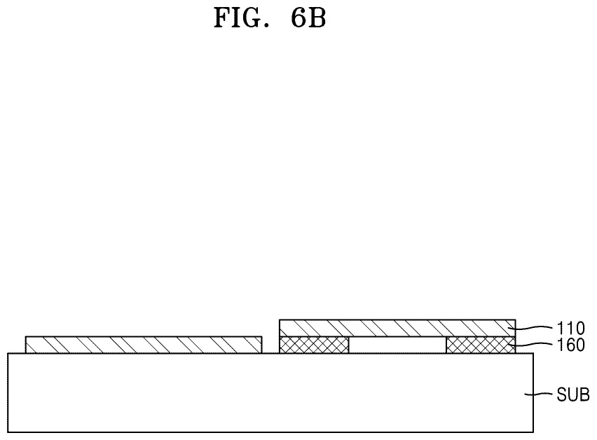

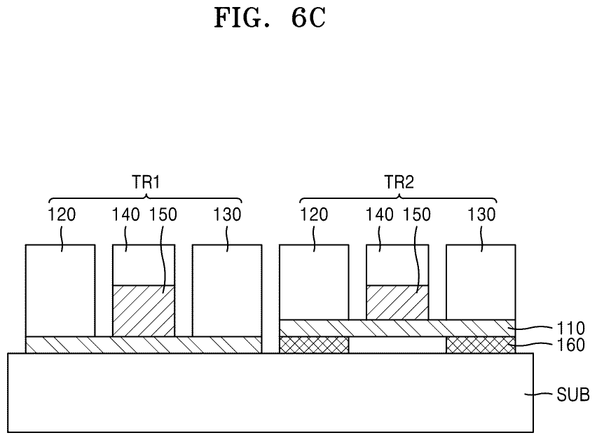

FIGS. 6A to 6C are diagrams illustrating a method of manufacturing a CMOS according to an embodiment.

As shown in FIG. 6A, a 2D material layer having an insulating property is formed on a substrate SUB and patterned to form the alignment adjusting layer 160. The substrate SUB may be provided in a flat plate shape extending along a surface. The substrate SUB is a material for forming a device and having an excellent mechanical strength or dimensional stability. Examples of the material in the substrate SUB may include a glass plate, a metal plate, a ceramic plate, plastic (polycarbonate resin, polyester resin, epoxy resin, silicon resin, fluoride resin, etc.), but one or more embodiments are not limited thereto.

As shown in FIG. 6B, a 2D material layer having a semiconductor characteristic is formed on the substrate SUB and patterned to form two channel layers 110.

In addition, as shown in FIG. 6B, the source electrode 120, the gate insulating layer 150, the gate electrode 140, and the drain electrode 130 are formed on each of the channel layers 110 to form the transistors TR1 and TR2. The first transistor TR1 that does not include the alignment adjusting layer 160 may be an n-type transistor, and the second transistor TR2 including the alignment adjusting layer 160 may be a p-type transistor. The CMOS may be easily manufactured through one process by using the alignment adjusting layer 160.

In FIGS. 6A to 6C, the CMOS may be manufactured by using the 2D materials having different types of insulating property.

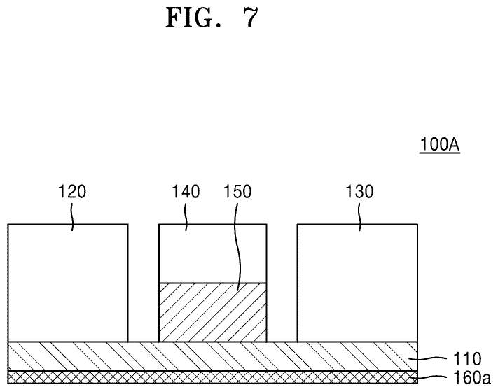

FIG. 7 is a diagram of a semiconductor device 100A including one alignment adjusting layer 160a according to an embodiment. When comparing FIG. 2 with FIG. 7, the alignment adjusting layer 160a of FIG. 7 may be disposed on the lower surface of the channel layer 110. The alignment adjusting layer 160a may overlap the source electrode 120, the drain electrode 130, and the gate electrode 140 in the thickness direction of the channel layer 110. The alignment adjusting layer 160a may provide the channel layer 110 more carriers, e.g., electrons or holes, and thus, the adjustment of the energy-band alignment may be easier.

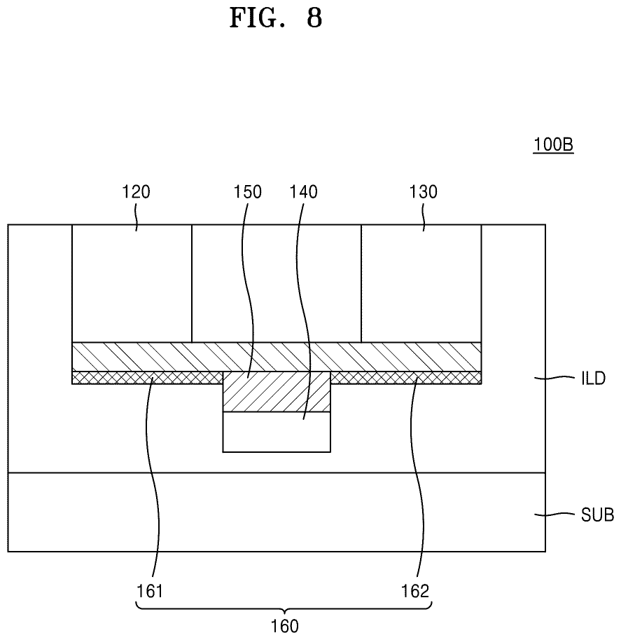

FIG. 8 is a diagram of a semiconductor device 100B having a bottom-gate structure according to an embodiment. When comparing FIG. 2 with FIG. 8, the source electrode 120 and the drain electrode 130 may be disposed on the upper surface of the channel layer 110 to be spaced apart from each other, and the gate electrode 140 may be disposed on the lower surface of the channel layer 110, in the semiconductor device 100b of FIG. 8. The gate insulating layer 150 may be between the channel layer 110 and the gate electrode 140.

The alignment adjusting layer 160 may be disposed on the lower surface of the channel layer 110. The alignment adjusting layer 160 may include the first alignment adjusting layer 161 overlapping the source electrode 120 and the second alignment adjusting layer 162 overlapping the drain electrode 130 in the thickness direction of the channel layer 110. Side surfaces of the first and second alignment adjusting layers 161 and 162 may be in contact with the gate insulating layer 150, but may be spatially spaced apart from the gate electrode 140.

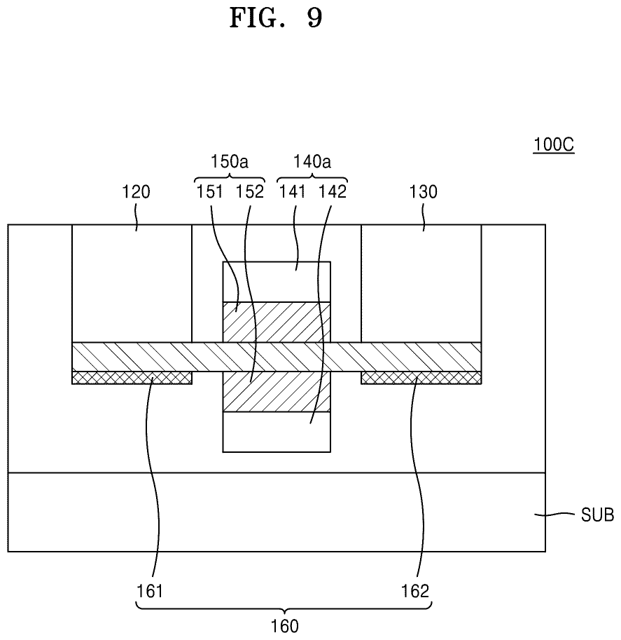

FIG. 9 is a diagram of a semiconductor device 100C having a double-gate structure according to an embodiment. When comparing FIG. 2 with FIG. 9, the gate insulating layer 150a may include a first gate insulating layer 151 on the upper surface of the channel layer 110, and a second gate insulating layer 152 on the lower surface of the channel layer 110. The gate electrode 140a may include a first gate electrode 141 on an upper surface of the first gate insulating layer 151, and a second gate electrode 142 on a lower surface of the second gate insulating layer 152.

The alignment adjusting layer 160 may be disposed on the lower surface of the channel layer 110. The alignment adjusting layer 160 may include the first alignment adjusting layer 161 overlapping the source electrode 120 and the second alignment adjusting layer 162 overlapping the drain electrode 130 in the thickness direction of the channel layer 110. Side surfaces of the first and second alignment adjusting layers 161 and 162 may be in contact with the gate electrode 140a, but may be spatially spaced apart from the gate electrode 140.

Although not shown in the drawings, the gate insulating layer 160 may be arranged on the semiconductor device in which the gate insulating layer 150 and the gate electrode 140 surround the channel layer 110.

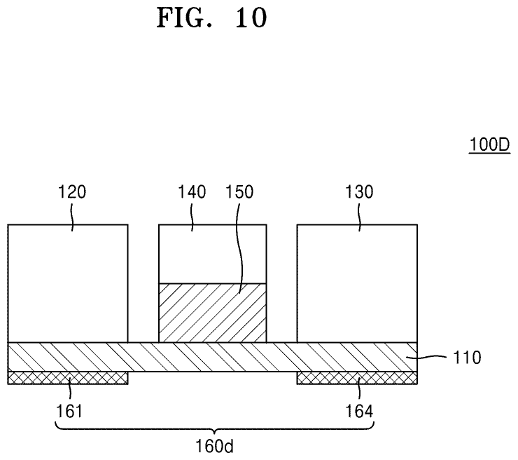

FIG. 10 is a diagram of a semiconductor device 100D including an alignment adjusting layer according to an embodiment.

When comparing FIG. 2 with FIG. 10, the alignment adjusting layer 160d of FIG. 10 may include a second alignment adjusting layer 164 instead of the second alignment adjusting layer 162 in FIG. 2. The second alignment adjusting layer 164 may have a wider width than a width of the first alignment adjusting layer 161 and a width of the second alignment adjusting layer 162.

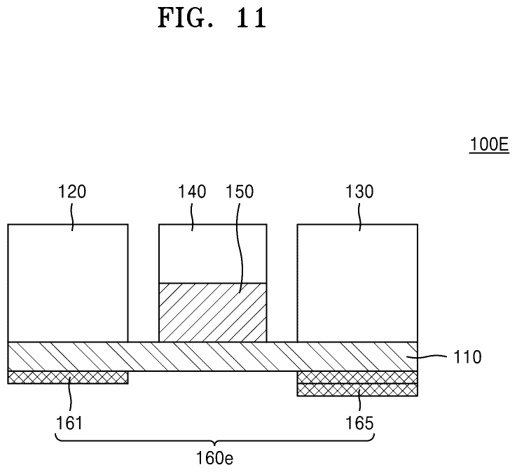

FIG. 11 is a diagram of a semiconductor device 100E including an alignment adjusting layer according to an embodiment.

When comparing FIG. 2 with FIG. 11, the alignment adjusting layer 160e of FIG. 11 may include a second alignment adjusting layer 165 instead of the second alignment adjusting layer 162 in FIG. 2. The second alignment adjusting layer 165 may have a greater thickness than a thickness of the first alignment adjusting layer 161 and a thickness of the second alignment adjusting layer 162.

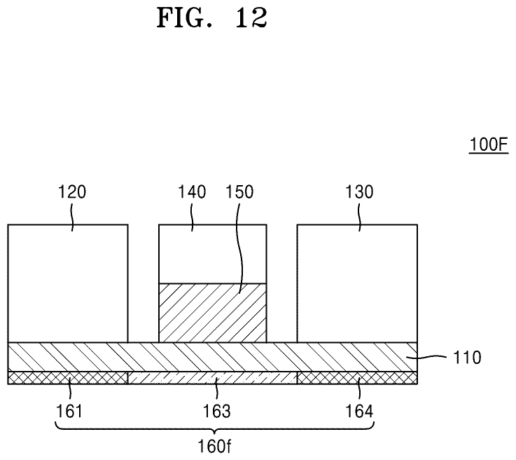

FIG. 12 is a diagram of a semiconductor device 100F including an alignment adjusting layer according to an embodiment.

When comparing FIG. 2 with FIG. 12, the alignment adjusting layer 160f of FIG. 12 may further include a third alignment adjusting layer 163 between the first alignment adjusting layer 161 and the second alignment adjusting layer 162. The third alignment adjusting layer 163 may be a different material than the first alignment adjusting layer 161 and the second alignment adjusting layer 162. For example, the first and second alignment adjusting layers 161 and 162 may include a material that may provide the channel layer 110 with holes and the third alignment adjusting layer 163 may be a material that may provide the channel layer 110 with electrons. Alternatively, the first and second alignment adjusting layers 161 and 162 may include a material that may provide the channel layer 110 with electrons and the third alignment adjusting layer 163 may be a material that may provide the channel layer 110 with holes.

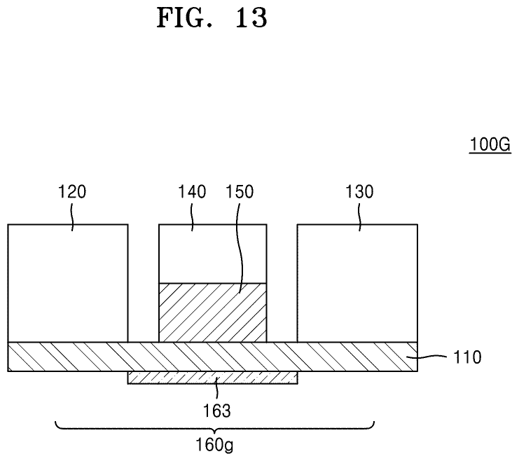

FIG. 13 is a diagram of a semiconductor device 100G including an alignment adjusting layer according to an embodiment.

When comparing FIG. 12 with FIG. 13, the alignment adjusting layer 160g of FIG. 13 may include the third alignment adjusting layer 163 under the gate electrode 140 on a bottom surface of the channel layer 110. However, the first alignment adjusting layer 161 and/or the second alignment adjusting layer 162 may be omitted in the semiconductor device 100G.

In the above description, the alignment adjusting layer may be arranged in order to adjust the energy-band alignment between the 2D material layer having semiconductor characteristics and the conductive layer, but one or more embodiments are not limited thereto. The alignment adjusting layer 13 may be arranged in order to adjust the energy-band alignment between a material layer having the semiconductor characteristic, other than the 2D material layer, and the conductive layer. The material layer having the semiconductor characteristic may be small in thickness for the energy-band alignment, for example, the thickness of the material layer having the semiconductor characteristic may be about 5 nm.

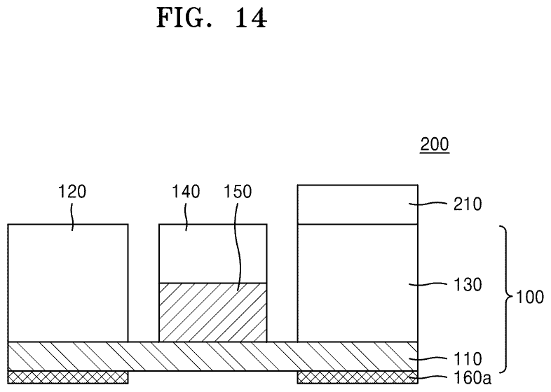

FIG. 14 is a diagram of a memory device 200 using a semiconductor device described above as a switching device and including a data storage element connected to the switching device.

Referring to FIG. 14, the memory device 200 includes a data storage element 210 on the interlayer insulating layer ILD. The data storage element 210 may entirely cover the upper surface of the drain electrode 130 and may be in direct contact with the upper surface. The data storage element 210 may include a capacitor, a ferroelectric capacitor, and a magnetic tunnel junction (MTJ) cell. The memory device 200 may be a volatile memory such as a dynamic random access memory (DRAM) or a non-volatile memory such as a ferroelectric RAM (FRAM), a magnetic RAM (MRAM), a resistance RAM (ReRAM), etc. according to the data storage element 210.

While FIG. 14 illustrates the memory device 200 with the semiconductor device 100 from FIG. 2, example embodiments are not limited thereto. The memory device 200 may include any one of the semiconductor devices 100 and 100A to 100G described above.

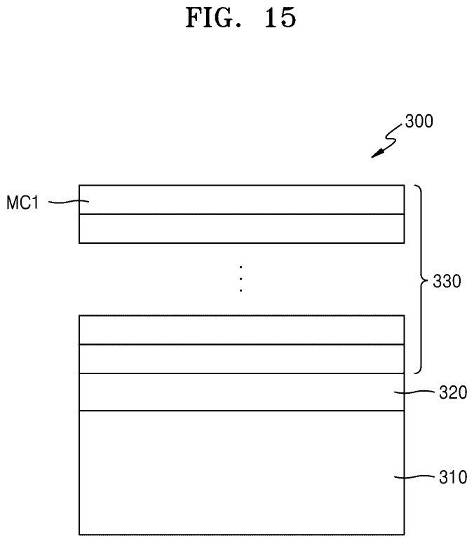

FIG. 15 is a diagram of a memory apparatus in which a plurality of memory devices MC1 of FIG. 14 are stacked vertically.

Referring to FIG. 15, a memory logic layer 320 controlling operations of the memory apparatus 300 is on a substrate 310, and a memory cell array 330 is provided on the memory logic layer 320. The memory cell array 330 includes a plurality of memory cells MC1 that are vertically stacked. In an example, the memory cell MC1 may include the memory device 200 of FIG. 14.

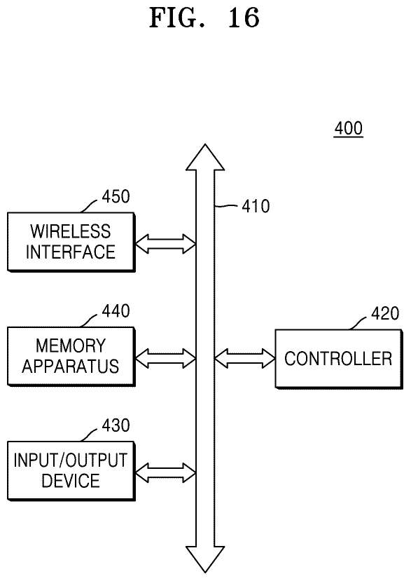

FIG. 16 is a block diagram schematically showing an electronic apparatus 400 including a memory apparatus according to an embodiment.

Referring to FIG. 16, the electronic apparatus 400 according to the embodiment may be one of a personal digital assistant (PDA), a laptop computer, a portable computer, a web tablet, a wireless phone, a mobile phone, a digital music player, a wired/wireless electronic appliance, and a combined electronic apparatus including at least two thereof. The electronic apparatus 400 may include a controller 420, an input/output device 430 such as a keypad, a keyboard, and a display, a memory apparatus 440, and a wireless interface 450 coupled to one another via a bus 410.

The controller 420 may include, for example, one or more microprocessors, a digital signal processor, a microcontroller, or equivalents thereof. The memory apparatus 440 may be used, for example, to store instructions executed by the controller 420.

The memory apparatus 440 may be used to store user data. The memory apparatus 440 may include the 2D material layer 11 according to the embodiment, a metal island, and a metal layer. The memory apparatus 440 and/or controller 420 may include any one of the semiconductor devices 100 and 100A to 100G described above, the memory device 200 described in FIG. 14, and/or the memory apparatus 300 described in FIG. 15.

The electronic apparatus 400 may use the wireless interface 450 in order to transmit/receive data to/from a wireless communication network that communicates via RF signals. For example, the wireless interface 450 may include an antenna, a wireless transceiver, etc. The electronic apparatus 400 may be used in a communication interface protocol such as third-generation communication system, e.g., code division multiple access (CDMA), global system for mobile communications (GSM), North American digital communications (NADC), extended time division multiple access (E-TDMA), wideband CDMA (WCDMA), and CDMA2000.

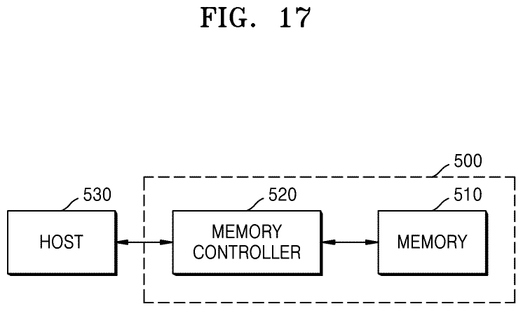

FIG. 17 is a block diagram schematically showing a memory system 500 including a volatile memory apparatus according to an embodiment.

Referring to FIG. 17, volatile memory apparatuses according to an embodiment may be used to implement a memory system. The memory system 500 may include a memory 510 for storing large-capacity data, and a memory controller 520. The memory controller 520 may control the memory 510 to read or write data from/to the memory 510 in response to read/write requests from a host 530. The memory controller 520 may include an address-mapping table for mapping a logical address provided from the host 530, for example, a mobile device or a computer system, to a physical address of the memory 510. The memory 510 may include the 2D material layer 11 according to the embodiment, a metal island, and a metal layer. The memory 510 and/or memory controller 520 may include any one of the semiconductor devices 100 and 100A to 100G described above, the memory device 200 described in FIG. 14 and/or the memory apparatus 300 described in FIG. 15.

The memory apparatus according to the embodiment described above may be implemented in the form of a chip and may be used as a neuromorphic computing platform.

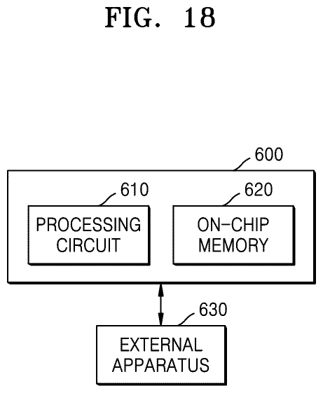

FIG. 18 is a schematic diagram of a neuromorphic apparatus 600 including a memory according to an embodiment. Referring to FIG. 18, the neuromorphic apparatus 600 may include a processing circuit 610 and an on-chip memory 620.

The processing circuit 610 may be configured to control functions for driving the neuromorphic apparatus 600. For example, the processing circuit 610 may execute programs stored in the on-chip memory 620 of the neuromorphic apparatus 600 to control the neuromorphic apparatus 600.

The processing circuit 610 may include hardware such as a logic circuit, a combination of hardware such as a processor executing software and software, or a combination thereof. For example, the processor may include a central processing unit (CPU), a graphics processing unit (GPU), an application processor (AP) in the neuromorphic apparatus 600, an arithmetic logic unit (ALU), a digital processor, a microcomputer, a field programmable gate array (FPGA), a system-on-chip (SoC), a programmable logic unit, a microprocessor, application-specific integrated circuit (ASIC), etc.

Also, the processing circuit 610 may read and write various data from and to an external apparatus 630 and execute the neuromorphic apparatus 600 by using the data. The external apparatus 630 may include a sensor array including an external memory and/or an image sensor (e.g., a CMOS image sensor circuit). The processing circuit 610 and/or on-chip memory 620 may include any one of the semiconductor devices 100 and 100A to 100G described above, the memory device 200 described in FIG. 14, and/or the memory apparatus 300 described in FIG. 15.

The neuromorphic apparatus 600 illustrated in FIG. 18 may be applied to a machine learning system. The machine learning system may utilize various processing models and various artificial neural network organizations including, for example, a convolutional neural network (CNN), a deconvolutional neural network, a recurrent neural network (RNN) selectively including a long short-term memory (LSTM) and/or a gated recurrent unit (GRU), a stacked neural network (SNN), a state-space dynamic neural network (SSDNN), a deep belief network (DBN), generative adversarial networks (GANs), and/or restricted Boltzmann machines (RBMs).

The machine learning system may include, for example, linear regression and/or logistic regression, statistical clustering, Bayesian classification, decision trees, dimensionality reduction such as principal component analysis, and another type of machine learning model such as an expert system, and/or a combination thereof including an ensemble technique such as random forest. The machine learning model may be used to provide various services, for example, an image classification service, a user authentication service based on biometric information or biometric data, an advanced driver assistance system (ADAS), a voice assistant service, and an automatic speech recognition (ASR) service and may be installed in other electronic apparatuses to be executed.

While the thin film structure 10, the manufacturing method therefor, and the apparatus including the same have been particularly shown and described with reference to example embodiments thereof, it will be understood by those of ordinary skill in the art that various changes in form and details may be made therein without departing from the spirit and scope as defined by the following claims. In the specification, many details are described in detail, but they are not provided to limit the scope of the disclosure, and should be interpreted as illustrating the embodiment. Thus, the scope of the disclosure should be determined by the technical idea set forth in the claims, not by the embodiments.

According to an embodiment, a layer capable of controlling the energy-band alignment between the 2D material layer and the conductive layer is arranged on the region of the 2D material layer having the semiconductor characteristic, other than the region coming into contact with the conductive layer, and thus, the type of the 2D material layer may be adjusted.

In the 2D material layer having the semiconductor characteristic, the layer capable of providing the 2D material layer with electrons or holes is arranged on a region other than the region coming into contact with the conductive layer, and thus, the contact resistance between the 2D material layer and the conductive layer may be reduced.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a two-dimensional (2D) material layer having a semiconductor characteristic;
a conductive layer on a first surface of the 2D material layer; and
an alignment adjusting layer on a second surface of the 2D material layer, the alignment adjusting layer adjusting an energy-band alignment between the 2D material layer and the conductive layer, the second surface of the 2D material layer being different from the first surface of the 2D material layer.

2. The semiconductor device of claim 1, wherein
the second surface of the 2D material layer is opposite the first surface of the 2D material layer.

3. The semiconductor device of claim 1, wherein
the alignment adjusting layer overlaps the conductive layer in a thickness direction of the 2D material layer.

4. The semiconductor device of claim 1, wherein
a thickness of the alignment adjusting layer is equal to or less than a thickness of the 2D material layer.

5. The semiconductor device of claim 1, wherein
the alignment adjusting layer includes a 2D material having an insulating property.

6. The semiconductor device of claim 1, wherein the alignment adjusting layer includes a material capable of providing the 2D material layer with holes.

7. The semiconductor device of claim 6, wherein a work function of the alignment adjusting layer is greater than an ionization energy of the 2D material layer.

8. The semiconductor device of claim 6, wherein
the alignment adjusting layer includes at least one of RuCl₃, NbS₂, MoO₃, Cr₂C₂O₂, V₂CF₂, Y₂CO₂, Hf₃C₂O₂, Y₄C₃O₂, VS₂, Ti₄C₃O₂, Ti₃C₂O₂, Cr₄N₃O₂, V₃C₂O₂, Mn₂NO₂, V₄C₃O₂, Mn₄N₃O₂, and V₂CO₂.

9. The semiconductor device of claim 1, wherein
the alignment adjusting layer includes a material capable of providing the 2D material layer with electrons.

10. The semiconductor device of claim 9, wherein
a work function of the alignment adjusting layer is less than an electron affinity of the 2D material layer.

11. The semiconductor device of claim 9, wherein
the alignment adjusting layer includes at least one of WO₃, Ca₂N, Sr₂N, Ba₂N, Y₂C, Gd₂C, Tb₂C, Dy₂C, Ho₂C, Mn₂NO₂H₂, Mn₂CO₂H₂, V₂CO₂H₂, Ti₄C₂O₂H₂, Ti₂CO₂H₂, Ti₂NO₂H₂, Ti₄N₃O₂H₂, Y₄N₃F₂, Hf₃C₂F₂, and Zr₃C₂F₂.

12. The semiconductor device of claim 1, wherein
the 2D material layer includes transition metal dichalcogenide (TMD).

13. The semiconductor device of claim 12, wherein
the TMD includes a metal element and a chalcogen element,
the metal element includes one of W, Nb, V, Ta, Ti, Zr, Hf, Tc, Re, Cu, Ga, In, Sn, Ge, and Pb, and
the chalcogen element includes one of S, Se, and Te.

14. The semiconductor device of claim 1, wherein
a thickness of the 2D material layer is 3 nm or less.

15. The semiconductor device of claim 1, wherein
the conductive layer includes a metal material.

16. The semiconductor device of claim 1, wherein
the conductive layer includes a first conductive layer and a second conductive layer,
the first conductive layer and the second conductive layer are spaced apart from each other, and
the alignment adjusting layer includes a first alignment adjusting layer overlapping the first conductive layer and a second alignment adjusting layer overlapping the second conductive layer in a thickness direction of the 2D material layer.

17. The semiconductor device of claim 16, further comprising
a transistor, wherein
the 2D material layer is a channel layer of the transistor,
a first one of the first conductive layer and the second conductive layer is a source electrode of the transistor, and
a second one of the first conductive layer and the second conductive layer is a drain electrode of the transistor.

18. The semiconductor device of claim 17, wherein
the alignment adjusting layer is spatially spaced apart from the gate electrode of the transistor.

19. The semiconductor device of claim 16, wherein
the first alignment adjusting layer and the second alignment adjusting layer are connected as different regions of a same alignment adjusting layer.

20. The semiconductor device of claim 16, wherein
the transistor includes a gate insulating layer, and
the first alignment adjusting layer, the second alignment adjusting layer, or both the first alignment adjusting layer and the second alignment adjusting layer contact the gate insulating layer.
